(19) United States
(12) Patent Application Publication
(10) Pub. No.: US 2020/0059249 A1
(43) Pub. Date: Feb. 20, 2020

(54) METHOD FOR POLAR CODE TRANSMISSION WITH PARTIAL INFORMATION AND DEVICES USING THE SAME

(71) Applicant: Industrial Technology Research Institute, Hsinchu (TW)

(72) Inventors: Shin-Lin Shieh, Hsinchu County (TW); Yu-Chih Huang, Taipei City (TW)

(73) Assignee: Industrial Technology Research Institute, Hsinchu (TW)

(21) Appl. No.: 16/540,076

(22) Filed: Aug. 14, 2019

Related U.S. Application Data
(60) Provisional application No. 62/718,391, filed on Aug. 14, 2018.

(51) Int. Cl. H03M 13/27; H03M 13/13; H04W 88/02; H04W 88/08

(52) U.S. Cl. CPC H03M 13/2742; H03M 13/13; H04W 88/08; H04W 88/02; H03M 13/271

(57) ABSTRACT

The disclosure provides a method and devices for transmitting information using polar code. In an exemplary embodiment in accordance with the disclosure, the disclosure is directed to a method of transmitting information using polar code. The method would include not limited to: generating a first data packet with a predetermined size and comprising data of multiple applications or multiple users; performing an interleaving operation which maps the first data packet based on a mapping algorithm to average the reliability of the data of multiple applications or multiple users; and generating a second data packet comprising interleaved first data packet.

### CROSS REFERENCE TO RELATED APPLICATION

This application claims the priority benefit of U.S. provisional application Ser. No. 62/718,391, filed on Aug. 14, 2018. The entirety of the above-mentioned patent application is hereby incorporated by reference herein and made a part of specification.

### TECHNICAL FIELD

The disclosure is directed to a method for polar code transmission with partial information and devices using the same method.

### BACKGROUND

Polar Code is adopted in 5G New Radio (NR) for control channel. Table 1 shows the coding schemes for the Transport CHannels (TrCHs) of 5G NR. 5G NR adopts Low Density Parity Check (LDPC) codes for the UpLink Shared CHannel (UL-SCH), the DownLink Shared CHannel (DL-SCH) and the Paging CHannel (PCH). 5G NR adopts Polar codes for the Broadcast CHannel (BCH).

TABLE 1

| TrCHs | Coding scheme |
|---|---|
| UL-SCH | LDPC |
| DL-SCH | |
| PCH | |
| BCH | Polar code |

Table 2 shows the coding schemes for the control information types of 5G NR. 5G NR adopts Block codes for the Uplink Control Information (UCI). 5G NR adopts Polar codes for UCI and the Downlink Control Information (DCI).

TABLE 2

| Control Information | Coding scheme |
|---|---|
| DCI | Polar code |
| UCI | Block code |
| | Polar code |

Wireless caching is considered to lower latency and/or enhance system throughput. Wireless caching may provide some prior knowledge (known bits) in certain scenarios such as duplicated transmissions, multiple transmission points, infrequent data update, user information exchange, etc.

Polar codes are novel codes proposed by E. Arikan. Polar codes are the first explicit construction of codes that achieve capacity of any binary memoryless symmetric (BMS) channel. Encoding and decoding complexity of polar codes is in the order of O(N*log N). List decoding and Cyclic Redundancy Check (CRC) can be applied to enhance short-length performance.

FIG. 1 illustrates an example of polar transformation performed by polar codes. The main idea of polar codes is to perform polar transformation and successive cancellation decoding. First, polar codes perform polar transformation during encoding. In the example of FIG. 1, U and V may be input vectors. X and Y may be output vectors. W may be a channel matrix. In FIG. 1, X=(U+V)×W and Y=V×W. Decoding may be performed by successive cancellation. First, U may be decoded from vectors X and Y. Then, V may be decoded from vectors X, Y and U.

FIG. 2 illustrates an example of assignment of frozen bits by the polar code. Due to the polar transformation, the channel is polarized either into an almost perfect channel or a useless channel. An almost perfect channel is almost noiseless. A useless channel is completely noisy. Thus, polar codes assign information and CRC/parity-check bits to perfect channels and freeze useless channels. For a code rate R, the polar code may select (1−R)×N bits in U Domain as frozen bits.

A polar code may use a polar sequence for a size N kernel. The polar sequence Q comprises indexes. The polar sequence is denoted Q={Q₀, Q₁, . . . , Q_{N-1}}. Bits encoded by the polar code have different reliability. Bits with lower indexes have lower reliability. Bits with higher indexes have higher reliability. Thus, reliability values of N code bits have the following relationship: W(Q₀)<W(Q₁)< . . . <W(Q_{N-1}). Polar codes use the bits with lower index as frozen bits. Polar codes groups the frozen bits in a frozen set. Indexes of the frozen bits are grouped in Q_{F}={Q₀, Q₁, . . . , Q_{|QF-1|}}. Information bits and CRC/parity-check bits are assigned higher index. Indexes of information bits and CRC/parity-check bits are grouped in Q₁={Q_{|QF|}, Q_{|QF+1|}, . . . , Q_{|QN-1|}}. Design of the polar sequence is about reliability ordering. Sequence design may target Binary Erasure Channels (BEC), Binary Symmetric Channel (BSC) and Additive White Gaussian Noise (AWGN) channels.

FIG. 3 illustrates an example of a polar sequence. The size of the polar sequence of FIG. 3 is N=64. FIG. 3 show the polar sequence Q divided into two columns. The left column includes the first 32 indexes of Q. The right column includes the last 32 indexes of Q. Q starts at the top of the left column. Q ends at the bottom of the right column. The indexes of the right column have higher reliability than the indexes of the left column. The indexes at the bottom of a column have higher reliability than the indexes at the top of a column. In other words, the indexes of the polar sequence are in ascending reliability order. In polar codes, frozen bits have lowest reliability. Thus, polar codes assign lower indexes to the frozen bits. In FIG. 3, indexes at the top of the left column of FIG. 3 are assigned to the frozen bits. Frozen set may have 14 bits {Q₀, Q₁, . . . , Q₁₈, Q₃₂}. Thus, an unfrozen set may have N−14=64−14=50 bits. Information bits and CRC/parity-check bits may be assigned to the unfrozen bits. The frozen set of FIG. 3 may not include Q₇, Q₁₁, Q₁₂, Q₁₃, Q₁₄ and Q₁₅.

Due to the polar transformation, differences in reliability among the unfrozen bits may be big. Frozen bits have lowest reliability. Among the indexes of the unfrozen bits, Q₁₂ has the lowest reliability. Q₆₃ has the highest reliability. In the example of FIG. 3, the number of unfrozen bits may be 50 bits. The number of information bits and CRC/parity-check bits may equal the number of unfrozen bits. Thus, the information bits and CRC/parity-check bits may be denoted as {b₀, b₁, . . . , b₄₈, b₄₉}. Considering the first six bits, the polar code may assign Q₇ to b₀, may assign Q₁₁ to b₁, may assign Q₁₂ to b₂, may assign Q₁₃ to b₃, may assign Q₁₄ to b₄, and may assign Q₁₅ to b₅. In a reliability rank of the 50 unfrozen bits, b₂ has the lowest reliability since Q₁₂ is assigned to b₂. Frozen bit b₂ may have reliability rank 50 among the 50 unfrozen bits. Similarly, since Q₇ may be assigned to b₀, b₀ may have reliability rank 44 among the 50 unfrozen bits. Since Q₁₁ may be assigned to b₁, b₁ may have reliability rank 43. Since Q₁₃ may be assigned to b₃, b₃ may have reliability rank 40. Since Q₁₄ may be assigned to b₄, b₄ may have reliability rank 38. Since Q₁₅ may be assigned to b₅, b₅ may have reliability rank 24. For the first six unfrozen bits, the total reliability rank may be 44+43+50+40+38+24=239.

Considering the last six bits, since the polar code may assign Q₅₈ to b₄₄, b₄₄ may have reliability rank 9 among the 50 unfrozen bits. Similarly, since the polar code may assign Q₅₉ to b₄₅, b₄₅ may have reliability rank 4. Since the polar code may assign Q₆₀ to b₄₆, b₄₆ may have reliability rank 8. Since the polar code may assign Q₆₁ to b₄₇, b₄₇ may have reliability rank 3. Since the polar code may assign Q₆₂ to b₄₈, b₄₈ may have reliability rank 2. Since the polar code may assign Q₆₃ to b₄₉, b₄₉ may have reliability rank 1. Thus, for the last six unfrozen bits, the total reliability rank may be 9+4+8+3+2+1=27.

The average reliability rank for the first six unfrozen bits may be 239/6=39.83. The average reliability rank for the last six unfrozen bits may be 27/6=4.5. Denote the reliability of bit bᵢ as W(bᵢ). Therefore, the reliability of the first six bits is much lower than the reliability of the last six bits.

$$Fact \text{:} \frac{{\sum }_{i = 0}^{5} W ( {b}_{i} )}{6} << \frac{{\sum }_{i = 44}^{49} W ( {b}_{i} )}{6}$$

FIG. 4 illustrates a wireless communication system. The wireless communication system may comprise a base station and several user equipment (UE): UE1, UE2, UE3 and UE4. The base station may transmit data to the UEs. The wireless communication system may use wireless caching. The base station may perform a broadcast with receiver side information. A UE may receive the messages with side information. UE may pre-store part of the messages into cache memory during off-peak periods of low data transmission. UE may or may not request those files later. Wireless caching is best suited for but not limited to multimedia content distribution.

FIG. 5 illustrates a wireless communication system which uses wireless caching. The base station may multicast messages W₁, W₂, . . . , Wₘ to users (UE1, UE2, UE3 and UE4). The base station may transmit data to the UEs. The wireless communication system may use wireless caching. The base station may perform a broadcast with receiver side information. In the example of FIG. 5, after the base station performs the broadcast, UE1 may receive and pre-store messages W₁ and W₂. UE2 may receive and pre-store message W₃. UE3 may receive and pre-store messages W₂ and W₄. UE3 may receive and pre-store messages W₁, W₂, W₅ and W₇. Thus, each user may already have a subset of messages as side information.

Most of the work in the literature assumes noiseless broadcasting. However, the physical channel is never noiseless. Some theoretic works have shown much potential of jointly designing channel coding and exploiting side information. These theoretic works are largely limited to the theoretical realm. Thus, practical code designs are called for.

Convolutional code (CC)-based design may design a CC that can combat with uncertainties while exploiting side information. However, CCs are far from optimal.

LDPC code-based design may design LDPC codes that can combat with uncertainties while exploiting side information. LDPC codes may be near optimal when the blocklength is large. However, LDPC codes show presence of error floors.

Algebraic codes guarantee to correct certain amount of errors. However, soft decoding of algebraic codes is very difficult. Performance of algebraic codes are not comparable to other codes.

The disclosure is directed to a method for polar code transmission with potential, unpredictable partial information and devices using the same method. The method of the disclosure may be implemented along with wireless caching in a wireless communication system. As described above, polar codes perform polar transformation. However, polar transformation may cause a big difference in reliability between bits with lower indexes and bits with higher indexes. The method of the disclosure reduces the differences in reliability between bits and improves performance of polar codes.

### SUMMARY OF THE DISCLOSURE

Accordingly, to address the above described difficulty, the disclosure provides a method of transmitting information using polar code, a base station (BS) and a user equipment (UE) using the same method.

In an aspect, the disclosure is directed to a method of transmitting information using polar code, and the method would include not limited to: generating a first data packet with a predetermined size and comprising data of multiple applications or multiple users; performing an interleaving operation which maps the first data packet based on a mapping algorithm to average the reliability of the data of multiple applications or multiple users; and generating a second data packet comprising interleaved first data packet.

In another aspect, the disclosure is directed to a BS, and the BS would include not limited to: a transmitter; a receiver; and a processor coupled to the transmitter and the receiver and configured to: generate a first data packet with a predetermined size and comprising data of multiple applications or multiple users; perform an interleaving operation which maps the first data packet based on a mapping algorithm to average the reliability of the data of multiple applications or multiple users; and generate a second data packet comprising interleaved first data packet.

In another aspect, the disclosure is directed to a UE, and the UE would include not limited to: a transmitter; a receiver; and a processor coupled to the transmitter and the receiver and configured to: generate a first data packet with a predetermined size and comprising data of multiple applications; perform an interleaving operation which maps the first data packet based on a mapping algorithm to average the reliability of the data of multiple applications or multiple users; and generate a second data packet comprising interleaved first data packet.

In order to make the aforementioned features and advantages of the present disclosure comprehensible, exemplary embodiments accompanied with figures are described in detail below. It is to be understood that both the foregoing general description and the following detailed description are exemplary, and are intended to provide further explanation of the disclosure as claimed.

It should be understood, however, that this summary may not contain all of the aspect and embodiments of the present disclosure and is therefore not meant to be limiting or restrictive in any manner. Also, the present disclosure would include improvements and modifications which are obvious to one skilled in the art.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 illustrates an example of polar transformation performed by polar codes.

FIG. 2 illustrates an example of assignment of frozen bits by the polar code.

FIG. 3 is an example of a polar sequence.

FIG. 4 illustrates a wireless communication system.

FIG. 5 illustrates a wireless communication system which uses wireless caching.

FIG. 6 is a flow chart which illustrates a method of transmitting information using polar codes according to one of the exemplary embodiments of the disclosure.

FIG. 7 illustrates an exemplary device according to one of the exemplary embodiments of the disclosure.

FIG. 8 illustrates a polar code transmitter according to one of the exemplary embodiments of the disclosure.

FIGS. 9A, 9B, 9C and 9D illustrate examples of scenario conditions in 5G communication systems.

FIG. 10 illustrates an example of scenario conditions of Vehicle-To-Everything (V2X) communication.

FIG. 11 illustrates a flowchart of an interleaver of the polar code transmitter according to one of the exemplary embodiments of the disclosure.

FIGS. 12A and 12B illustrate examples of S-interleavers used by the polar code transmitter according to exemplary embodiments of the disclosure.

FIG. 13 illustrates an example of a rectangular interleaver used by the polar code transmitter according to exemplary embodiments of the disclosure.

FIG. 14 illustrates an example of a triangular interleaver used by the polar code transmitter according to exemplary embodiments of the disclosure.

FIGS. 15 and 16 illustrate examples of subsets output by S-interleavers according to exemplary embodiments of the disclosure.

FIG. 17 illustrates an example of subsets output by a rectangular interleaver according to exemplary embodiments of the disclosure.

FIG. 18 illustrates an example of subsets output by a triangular interleaver according to exemplary embodiments of the disclosure.

FIG. 19 illustrates Bit Error Rate (BER) performance of the polar code transmitter according to the exemplary embodiments of the disclosure.

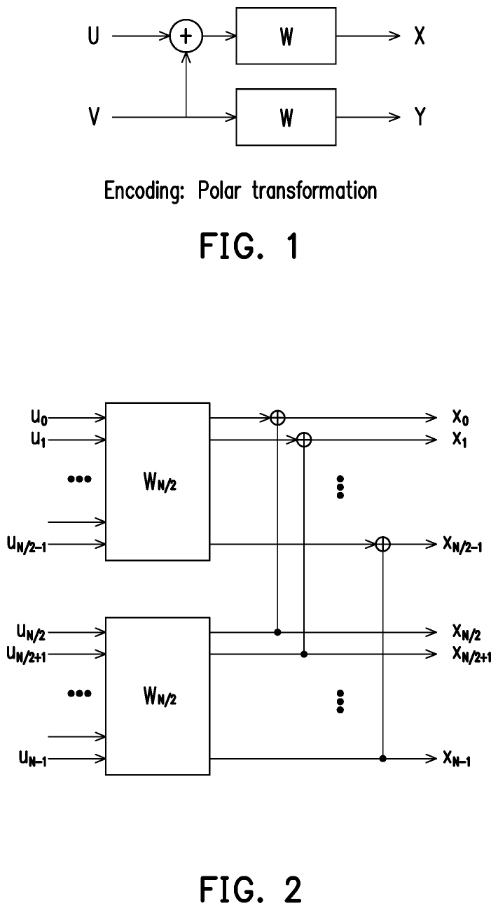

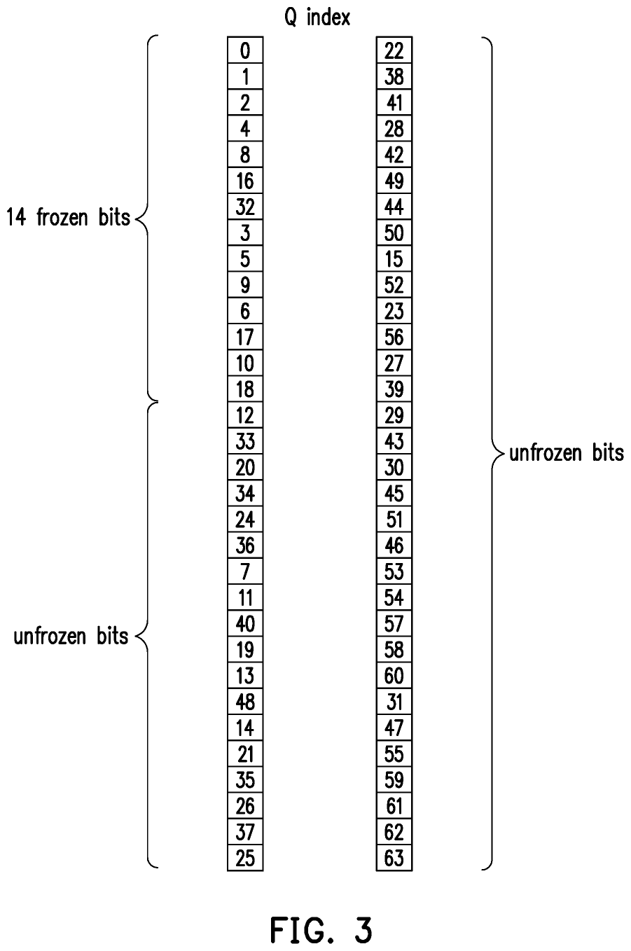

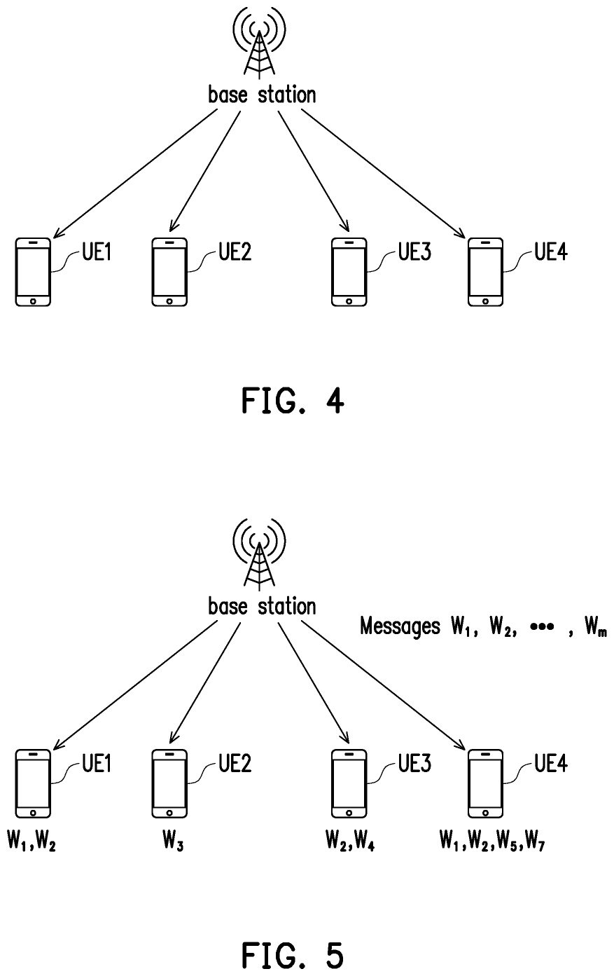

### DETAILED DESCRIPTION OF DISCLOSED EMBODIMENTS

Reference will now be made in detail to the present exemplary embodiments of the disclosure, examples of which are illustrated in the accompanying drawings. Wherever possible, the same reference numbers are used in the drawings and the description to refer to the same or like parts.

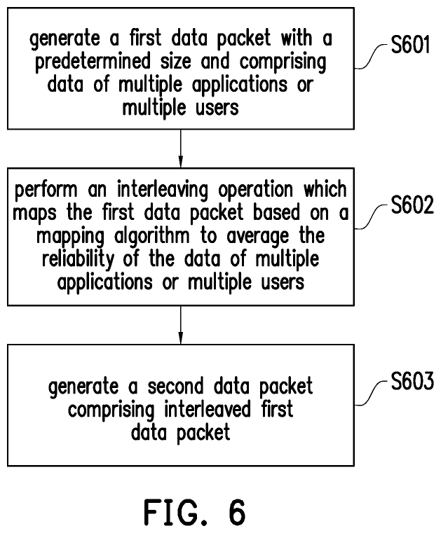

Accordingly, to address the above described difficulty, the disclosure provides a method for polar code transmission with partial information and devices using the same method. FIG. 6 is a flow chart which illustrates a method of transmitting information using polar codes according to one of the exemplary embodiments of the disclosure. The method may be implemented either at a base station (BS) or at a user equipment (UE). Both BS and UE comprise transmitters which may perform the method of the disclosure. BS may perform the method of the disclosure to transmit information to a UE. UE may perform the method of the disclosure to transmit information to a BS. The method of the disclosure may also be implemented for transmission from UE to UE. Referring to FIG. 6, in step S601, the transmitter may generate a first data packet with a predetermined size and comprising data of multiple applications or multiple users. In step S602, the transmitter may perform an interleaving operation which maps the first data packet based on a mapping algorithm to average the reliability of the data of multiple applications or multiple users. In step S603, the transmitter may generate a second data packet comprising interleaved first data packet.

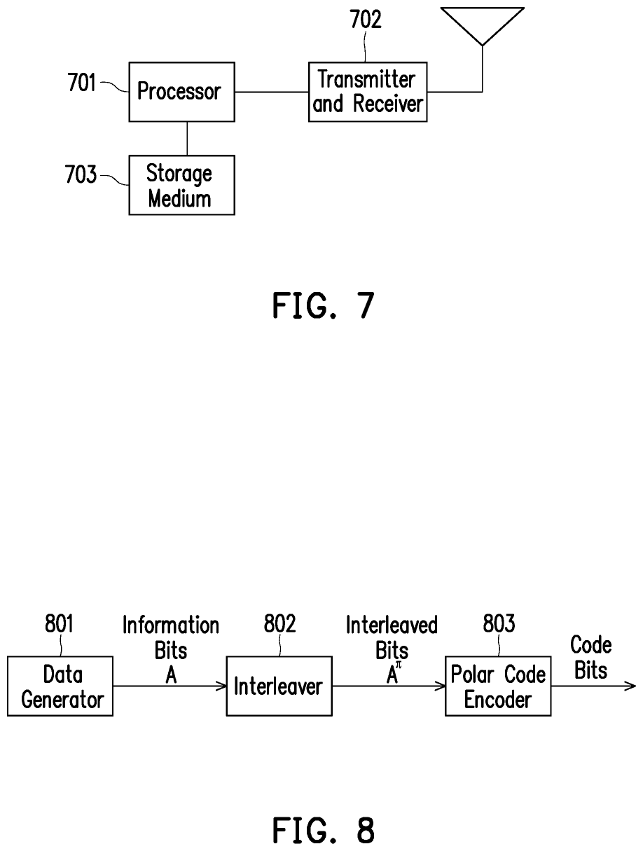

FIG. 7 illustrates an exemplary device according to one of the exemplary embodiments of the disclosure. The exemplary device may be a BS or a UE. The hardware of the exemplary device would include not limited to a hardware processor 701, a hardware transceiver 702 which may include integrated or separate transmitter and receiver, and non-transitory storage medium 703. The hardware processor 701 is electrically connected to the hardware transceiver 702 and the non-transitory storage medium 703 and configured at least for implementing the method for polar code transmission with partial information as well as its exemplary embodiments and alternative variations.

The hardware transceiver 702 may include one or more transmitters and receivers configured to transmit and receive signals respectively in the radio frequency or in the mmWave frequency. The hardware transceiver 702 may also perform operations such as low noise amplifying, impedance matching, frequency mixing, up or down frequency conversion, filtering, amplifying, and so forth. The hardware transceiver 702 may each include one or more analog-to-digital (A/D) and digital-to-analog (D/A) converters which are configured to convert from an analog signal format to a digital signal format during uplink signal processing and from a digital signal format to an analog signal format during downlink signal processing. The hardware transceiver 702 may further include an antenna array which may include one or multiple antennas to transmit and receive omni-directional antenna beams or directional antenna beams.

The hardware processor 701 is configured to process digital signals and to perform procedures of the proposed method for polar code transmission with partial information in accordance with the proposed exemplary embodiments of the disclosure. Also, the hardware processor 701 may access to the non-transitory storage medium 703 which stores programming codes, codebook configurations, buffered data, and record configurations assigned by the hardware processor 701. The hardware processor 701 could be implemented by using programmable units such as a micro-processor, a micro-controller, a DSP chips, FPGA, etc. The functions of the hardware processor 701 may also be implemented with separate electronic devices or ICs. It should be noted that the functions of hardware processor 701 may be implemented with either hardware or software.

As previously described, in conventional polar codes, since the polar transformation may cause a big difference in reliability between bits with lower indexes and bits with higher indexes, performance of the polar codes is reduced. One of the main concepts of the disclosure is to perform interleaving of the information bits before encoding with polar codes. Under such implementation, reliability of the bits is averaged, and differences in reliability among the bits are reduced.

FIG. 8 illustrates a polar code transmitter according to one of the exemplary embodiments of the disclosure. In the example of FIG. 8, the polar code transmitter may comprise a data generator 801, an interleaver 802, and a polar code encoder 803. Data generator 801, interleaver 802, and polar code encoder 803 are coupled to each other. Data generator 801 generates a vector of information bits. The vector of information bits has a predetermined size A. The input of interleaver 802 is the vector of information bits. Interleaver 802 then outputs interleaved bits A^{π}. The number of interleaved bits A^{π} equals the number of information bits. In other words, the number of interleaved bits A^{π} equals predetermined size A. The input of polar code encoder 803 is the interleaved bits A^{π}. Polar code encoder 803 performs encoding of the polar code and outputs code bits. Finally, the polar code transmitter transmits the code bits.

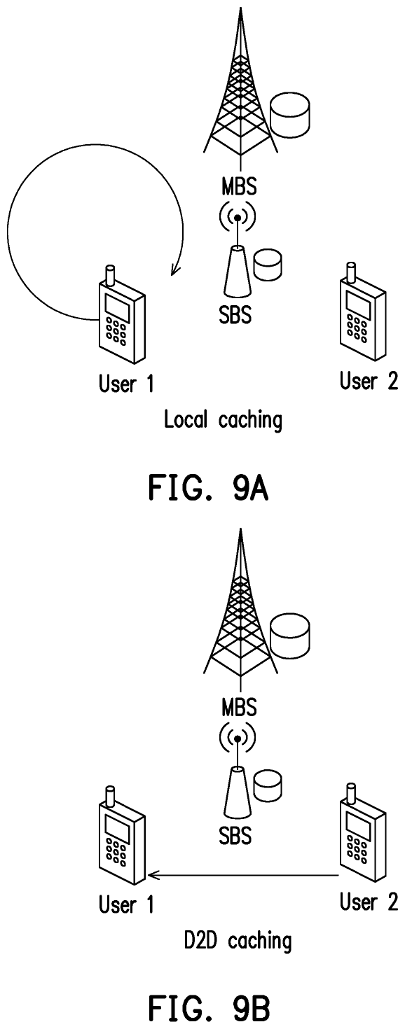

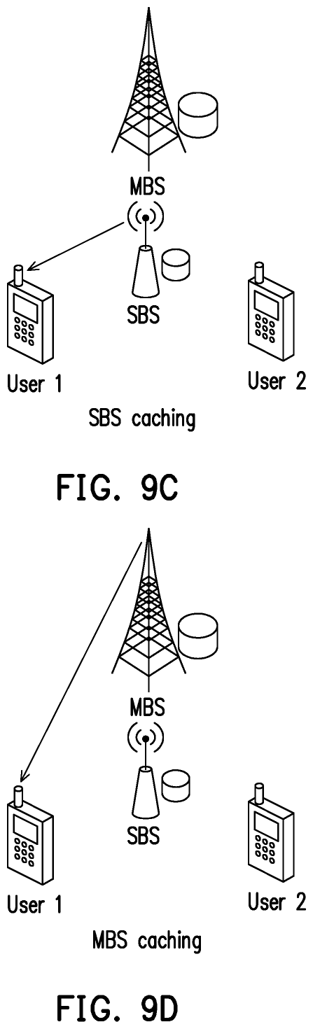

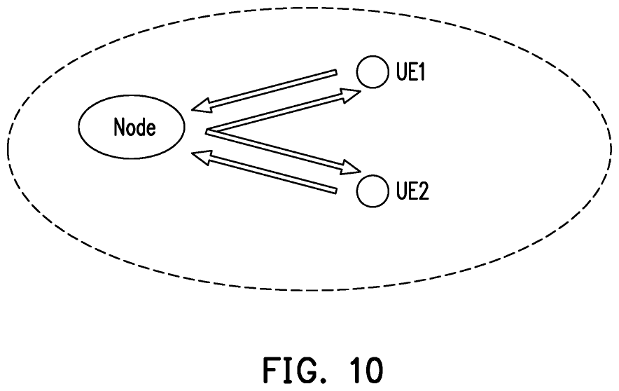

FIGS. 9A, 9B, 9C, 9D and 10 illustrate examples of different scenario conditions for wireless caching. Particularly, FIGS. 9A, 9B, 9C and 9D illustrate scenario conditions in 5G communication systems. FIG. 10 illustrates a scenario condition of Vehicle-To-Everything (V2X) communication.

FIGS. 9A, 9B, 9C and 9D illustrate examples of scenario conditions in 5G communication systems. A 5G communication system may comprise a macro-base station (MBS) and a small base station (SBS) providing network access to a plurality of users or UEs. The 5G communication system may be part of a network with an architecture which may include Cloud Radio Access Network (C-RAN), Fog Radio Access Network (F-RAN), Multi-access Edge Computing (MEC) or IAB. Literature in this area shows that caching may enhance data rate and/or reduce latency.

FIG. 9A shows an example of local caching. In local caching, caching may be performed within the device. UE 1 (the device of user 1) may pre-store a sub-file. MBS, SBS or UE 2 (the device of user 2) may send another sub-file to UE 1, and UE 1 may join the sub-files into a file.

FIG. 9B shows an example of Device-To-Device (D2D) caching. UE 2 may send a sub-file to UE 1. UE 1 may pre-store the received sub-file. Similarly, MBS, SBS or UE 2 may send another sub-file to UE 1, and UE 1 may join the sub-files into a file.

FIG. 9C shows an example of SBS caching. SBS may send a sub-file to UE 1. UE 1 may pre-store the received sub-file. Similarly, MBS, SBS or UE 2 may send another sub-file to UE 1, and UE 1 may join the sub-files into a file.

FIG. 9D shows an example of MBS caching. MBS may send a sub-file to UE 1. UE 1 may pre-store the received sub-file. Similarly, MBS, SBS or UE 2 may send another sub-file to UE 1, and UE 1 may join the sub-files into a file.

Release 16 of the specifications for 5G communication systems include items IAB and D2D.

FIG. 10 illustrates an example of scenario conditions of V2X communication. In V2X, vehicles exchange information. FIG. 10 shows a node, UE1 and UE2. UE1 may be on a vehicle. UE2 may be on another vehicle. The node may be a Road Side Unit (RSU). In stage 1, in other words pre-storing, each UE may send information to the RSU. In stage 2, in other words delivering user requests, RSU may broadcast combined information to all UEs. Before decoding, each UE knows its own information. Wireless caching strives to provide equal gain for all UEs.

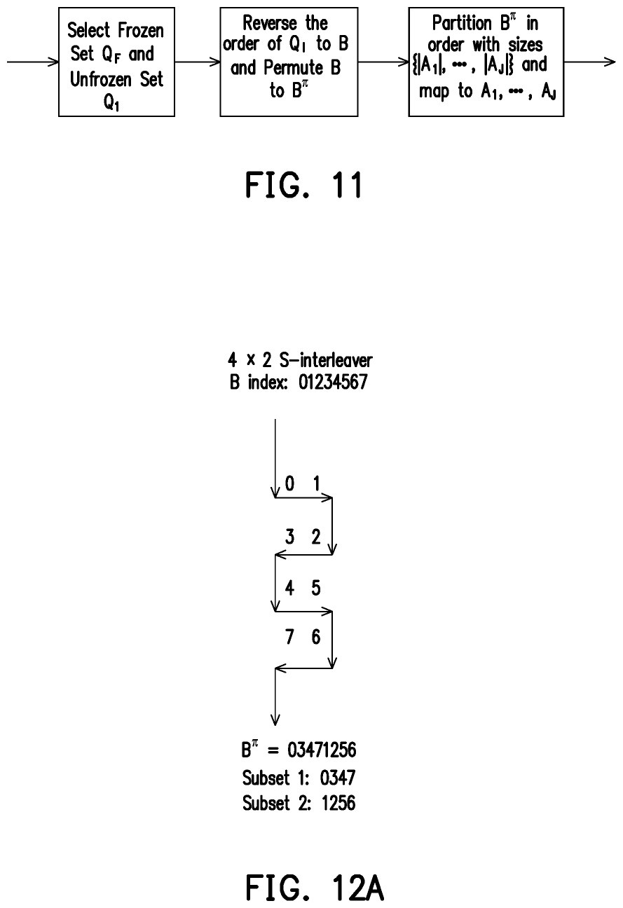

FIG. 11 illustrates a flowchart of an interleaver of the polar code transmitter according to one of the exemplary embodiments of the disclosure. The interleaver of FIG. 11 may be used in the polar code transmitter of FIG. 8 instead of interleaver 802.

As previously mentioned, the disclosure is directed to a method for polar code transmission. In conventional polar codes, there may be a big difference in reliability between bits with lower indexes and bits with higher indexes. One of the main concepts of the disclosure is to perform interleaving of the information bits before encoding with polar codes. Additionally, the method of the disclosure may be implemented along with wireless caching, where a file is partitioned into sub-files. Thus, the interleaver of FIG. 11 first may partition a set A into J subsets A₁, A₂, . . . , A_{J}. The interleaver may assign indexes to the subsets Aⱼ, j=1, 2, . . . , J, with almost equal reliability. The target of the interleaver is to provide almost equal gain per cached bit of the subsets Aⱼ.

First, reliability of bits b₁, W(bᵢ), and reliability rank (from the bottom), Qbᵢ, are defined. The criterions of average reliability comparison and average reliability rank comparison are shown as follows.

$$\frac{{\sum }_{i ∈ {A}_{2}} W ( {b}_{i} )}{\vert {A}_{2} \vert} \approx \frac{{\sum }_{i ∈ {A}_{1}} W ( {b}_{i} )}{\vert {A}_{1} \vert} ( average reliability comparison )$$

$$\frac{{\sum }_{i ∈ {A}_{2}} Q {b}_{i}}{\vert {A}_{2} \vert} \approx \frac{{\sum }_{i ∈ {A}_{1}} Q {b}_{i}}{\vert {A}_{1} \vert} ( average reliability rank comparison )$$

The input of the interleaver of FIG. 11 may be the polar sequence Q. The information size may be K. The size of the subsets may be |Aⱼ|, for j=1, 2, . . . , J, where Σⱼ|Aⱼ|=K. The goal of the interleaver is to attain J subsets (A₁, A₂, . . . , A_{J}) with almost equal reliability. The polar sequence Q is specified in technical specification TS 38.212 of the 3rd Generation Partnership Project (3GPP). However, other methods to generate alternative Q are not precluded. Interleaving may be implemented by permuting the unfrozen set Q_{I} before partitioning into J subsets (A₁, A₂, . . . , A_{J}). Using an interleaver, such as a S-interleaver, a rectangular interleaver, or a triangular interleaver is a good choice.

In FIG. 11, the input of the interleaver may be the polar sequence Q. First, the interleaver may select frozen set Q_{F} and unfrozen set Q_{I} from the polar sequence Q. Then, the interleaver may reverse the order of Q_{I} to the information bits B, and may permute B to output the interleaved bits B^{π}. Lastly, the interleaver may partition B^{π} in order according to sizes {|A₁|, |A₂|, . . . , |A_{J}|} and may map the interleaved bits B^{π} into subsets A₁, A₂, . . . , A_{J}.

Permutation performed by the interleaver is described as follows. Indexes for a length-N polar code may be Qᵢ for i=0, 1, . . . , N−1. 3GPP TS 38.212 standard provides the indexes in the sequence Q={0, 1, 2, 4, . . . }. Q₀ may be the index with the lowest reliability. Q_{N-1} may be the index with the highest reliability. (N−K) frozen bit positions may be selected for the frozen set Q_{F}={Q₀, Q₁, . . . , Q_{N-K-1}}. K unfrozen bit positions may be selected for the unfrozen set Q_{I}={Q_{N-K}, Q_{N-K+1}, . . . , Q_{N-1}}. Indexes of the unfrozen set Q_{I} may be reversed to obtain reverse(Q_{I})={Q_{N-1}, Q_{N-2}, . . . , Q_{N-K+1}, Q_{N-K}}. Then, information bits B may be assigned to reverse(Q_{I}). In other words, B={B₀, B₁, . . . , B_{K-1}}=reverse(Q_{I})={Q_{N-1}, Q_{N-2}, . . . , Q_{N-K+1}, Q_{N-K}}. Thus, information bit B₀ may be assigned the index with the highest reliability. Then B may be interleaved to output B^{π}={B₀^{π}, B₁^{π}, . . . , B_{K-1}^{π}}. Finally, {B₀^{π}, B₁^{π}, . . . , B_{|A}_{₁}_{|-1}^{π}} may be assigned to A₁, {B₀^{π}, B₁^{π}, . . . , B_{|A}_{₁}_{|+|A}_{₂}_{|-1}^{π}} may be assigned to A₂, so on and so forth.

As a summary of the description of FIG. 11, the interleaver performs the following steps to assign the indexes of a polar sequence to the frozen bits and the information bits of a first data packet (information bits are unfrozen bits): selecting a frozen set of indexes from a polar sequence, the polar sequence comprising a plurality of indexes; assigning the indexes of the frozen set to frozen bits of the polar code; selecting an unfrozen set of indexes from the polar sequence; and assigning the indexes of the unfrozen set to the first data packet. Furthermore, the interleaver assigns the indexes of the unfrozen set to the first data packet by: reversing the order of the indexes of the unfrozen set; and assigning the reversed indexes of the unfrozen set to bits of the first packet data.

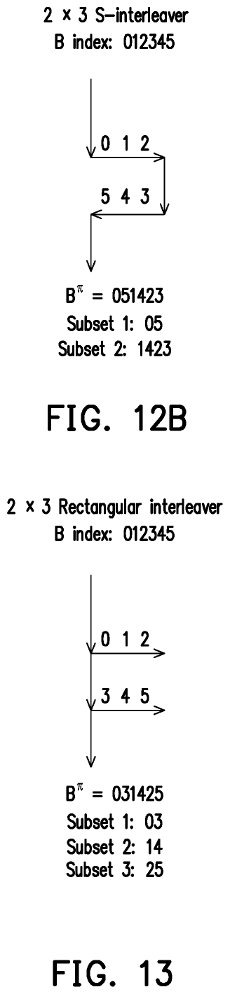

FIGS. 12A, 12B, 13 and 14 illustrate examples of interleavers used by the polar code transmitter according to exemplary embodiments of the disclosure. The input of the interleavers of FIGS. 12A, 12B, 13 and 14 may be the information bits B after being assigned reverse(Q_{I}). The output of these interleavers may be the interleaved bits B^{π} assigned to the subsets A₁, A₂, . . . , A_{J}.

FIGS. 12A and 12B illustrate examples of S-interleavers used by the polar code transmitter according to exemplary embodiments of the disclosure. The S-interleaver may form a M×N matrix with the indexes of the input bits. The S-interleaver may perform a S-read-in row by row, and may perform linear read-out column by column.

FIG. 12A illustrates an example of S-interleaver. The S-interleaver of FIG. 12A is a 4×2 S-interleaver. Input of the S-interleaver may have eight bits. The S-interleaver of FIG. 12A may output two subsets with equal size 4. The S-interleaver may first perform a S-read-in row by row of the input bits. After performing S-read-in, the 4×2 S-interleaver may form a 4×2 matrix. Then the S-interleaver may perform a linear read-out column by column of the input bits. The first column of FIG. 12A shows indexes 0, 3, 4 and 7. The second column of FIG. 12A shows indexes 1, 2, 5 and 6. Thus, the indexes of the interleaved bits B^{π} are=0, 3, 4, 7, 1, 2, 5, 6. Linear read-out of the columns outputs: subset 1=0, 3, 4, 7; and subset 2=1, 2, 5, 6.

FIG. 12B illustrates another example of S-interleaver. The S-interleaver of FIG. 12B is a 2×3 S-interleaver. Input of the S-interleaver may have six bits. Different from the example of FIG. 12A, the S-interleaver of FIG. 12B may output two subsets with different sizes. The S-interleaver may first perform a S-read-in row by row of the input bits. After performing S-read-in, the 2×3 S-interleaver may form a 2×3 matrix. Then the S-interleaver may perform a linear read-out column by column of the input bits. The first column of FIG. 12B shows indexes 0 and 5. The second column of FIG. 12B shows indexes 1 and 4. The third column of FIG. 12B shows indexes 2 and 3. Thus, the indexes of the interleaved bits B^{π} are=0, 5, 1, 4, 2, 3. The interleaver of FIG. 12B outputs subset 1 with two bits, and outputs subset 2 with four bits. Thus, linear read-out outputs: subset 1=0, 5; and subset 2=1, 4, 2, 3.

FIG. 13 illustrates an example of a rectangular interleaver used by the polar code transmitter according to exemplary embodiments of the disclosure. A rectangular interleaver may form a M×N matrix with the indexes of the input bits. A rectangular interleaver may perform a linear read-in row by row, and may perform linear read-out column by column.

FIG. 13 illustrates an example of a 2×3 rectangular interleaver. Input of the rectangular interleaver may have six bits. The rectangular interleaver of FIG. 13 may output three subsets with equal size 2. The rectangular interleaver may first perform a linear read-in row by row of the input bits. After performing linear read-in, the 2×3 rectangular interleaver may form a 2×3 matrix. Then the rectangular interleaver may perform a linear read-out column by column of the input bits. The first column of FIG. 13 shows indexes 0 and 3. The second column of FIG. 13 shows indexes 1 and 4. The third column of FIG. 13 shows indexes 2 and 5. Thus, the indexes of the interleaved bits B^{π} are=0, 3, 1, 4, 2, 5. Linear read-out of the columns outputs: subset 1=0, 3; subset 2=1, 4; and subset 3=2, 5.

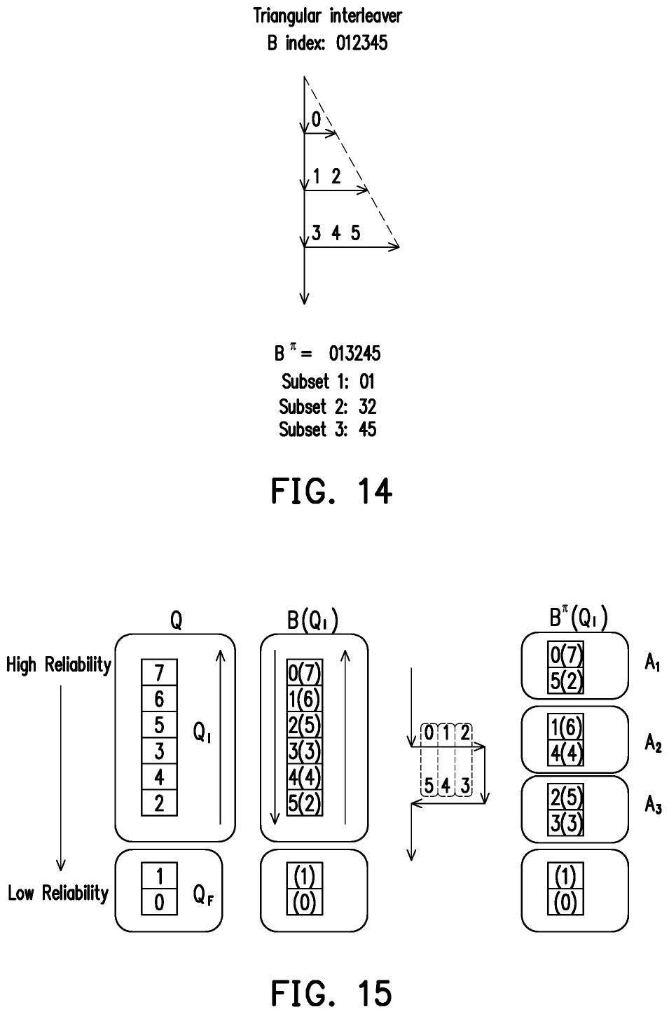

FIG. 14 illustrates an example of a triangular interleaver used by the polar code transmitter according to exemplary embodiments of the disclosure. A triangular interleaver may form a triangular matrix with the indexes of the input bits. A triangular interleaver may perform a linear read-in row by row, and may perform linear read-out column by column.

FIG. 14 illustrates an example of a triangular interleaver. Input of the triangular interleaver may have six bits. The triangular interleaver of FIG. 14 may output three subsets with equal size 2. The triangular interleaver may first perform a linear read-in row by row of the input bits. After performing linear read-in, the triangular interleaver may form a triangular matrix. Then the triangular interleaver may perform a linear read-out column by column of the input bits. The first column of FIG. 14 shows indexes 0, 1 and 3. The second column of FIG. 14 shows indexes 2 and 4. The third column of FIG. 14 shows index 5. Thus, the indexes of the interleaved bits B^{π} may be=0, 1, 3, 2, 4, 5. Linear read-out may output: subset 1=0, 1; subset 2=3, 2; and subset 3=4, 5.

FIGS. 12A, 12B, 13 and 14 illustrate examples of interleavers used by the polar code transmitter according to exemplary embodiments of the disclosure. However, the disclosure is not limited by the examples in these embodiments. The polar code transmitter of the disclosure may also use other types of interleavers. For example, the polar transmitter may also use a random interleaver.

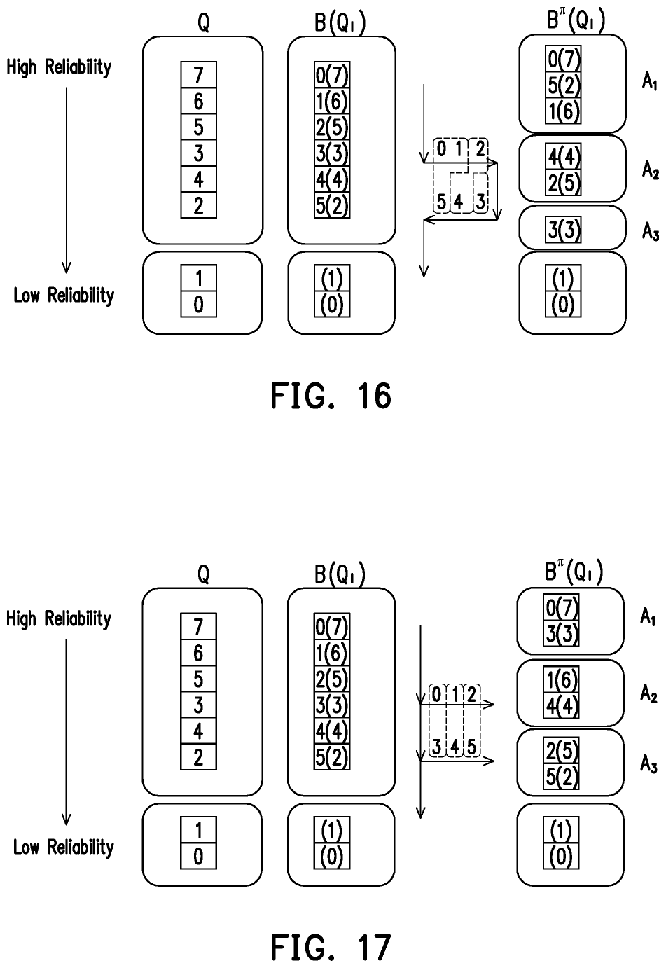

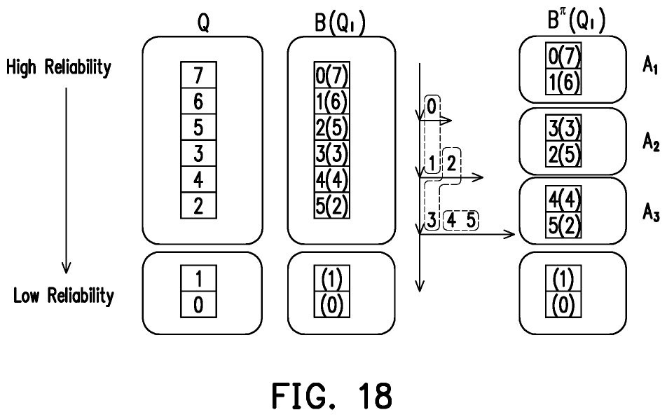

FIGS. 15, 16, 17 and 18 illustrate examples of subsets output by the interleavers according to exemplary embodiments of the disclosure. The subsets may correspond to sub-files in wireless caching. Each sub-file, if cached, may provide almost equal gain per cached bit. The input of the interleavers of FIGS. 15, 16, 17 and 18 may be the information bits B. From left to right, FIGS. 15, 16, 17 and 18: polar sequence Q and selection of frozen set Q_{F} and unfrozen set Q_{I} from polar sequence Q; followed by reversing of the indexes of unfrozen set Q_{I} to obtain reverse(Q_{I}); interleaving of information bits B to output interleaved bits B^{π}; and finally, outputting subsets A₁, A₂, . . . , A_{J} according to B^{π}. Interleaving of B is different in FIGS. 15, 16, 17 and 18. FIGS. 15 and 16 show examples using S-interleavers. FIG. 17 shows an example using a rectangular interleaver. FIG. 18 shows an example using a triangular interleaver.

First of all, frozen set Q_{F} and unfrozen set Q_{I} may be selected from polar sequence Q. FIGS. 15, 16, 17 and 18 show Q_{F} at the bottom. The frozen bits may be assigned indexes with the lowest reliability Q₀ and Q₁. B may have six information bits. Thus, unfrozen set Q_{I} may include six indexes Q₂, Q₃, Q₄, Q₅, Q₆ and Q₇. Indexes may be ordered according to their reliability. Indexes at the top of the Figures may have higher reliability. Indexes at the bottom of the Figures may have lower reliability.

The method follows by reversing the indexes of unfrozen set Q_{I} to obtain reverse(Q_{I}). Then, information bits B may be assigned to reverse(Q_{I}). Information bit B₀ is assigned to the index with highest reliability Q₇. From among the indexes of the unfrozen set Q_{I}, Q₂ is the index with lowest reliability. Information bit B₅ is assigned to index Q₂. In the examples of FIGS. 15, 16, 17 and 18, {B₀, B₁, B₂, B₃, B₄, B₅}=reverse(Q_{I})={Q₇, Q₆, Q₅, Q₃, Q₄, Q₂}. Following this step, interleaving is performed. Since interleaving is different in these examples, description for each example is provided as follows.

FIGS. 15 and 16 illustrate examples of subsets output by S-interleavers according to exemplary embodiments of the disclosure. FIGS. 15 and 16 show a 2×3 S-interleaver. FIG. 15 shows subsets A₁, A₂ and A₃ with equal size 2. FIG. 16 shows subsets A₁, A₂ and A₃ with unequal size.

The S-interleaver of FIGS. 15 and 16 may first perform a S-read-in row by row of the input bits. After performing S-read-in, the 2×3 S-interleaver may form a 2×3 matrix. Then the S-interleaver may perform a linear read-out column by column of the input bits. The first column of FIGS. 15 and 16 show indexes 0 and 5. The second column shows indexes 1 and 4. The third column shows indexes 2 and 3. Thus, the indexes of the interleaved bits B^{π} may be=0, 5, 1, 4, 2, 3.

FIG. 15 shows subsets A₁, A₂ and A₃ with equal size 2. Thus, linear read-out may output: subset A₁={0, 5}; subset A₂={1, 4}; and subset A₃={2, 3}. FIG. 16 shows subsets A₁, A₂ and A₃ with unequal sizes: |A₁|=3; |A₂|=2; and |A₃|=1. Linear read-out may output: subset A₁={0, 5, 1}; subset A₂={4, 2}; and subset A₃={3}.

The method of transmitting information using polar codes of FIG. 6 may use a S-interleaver to perform step S602. A first data packet may comprise the information bits. Using S-interleaving, a transmitter may perform the interleaving operation which maps the first data packet based on a S-interleaving mapping algorithm.

FIG. 17 illustrates an example of subsets output by a rectangular interleaver according to exemplary embodiments of the disclosure. FIG. 17 shows a 2×3 rectangular interleaver. FIG. 17 shows subsets A₁, A₂ and A₃ with equal size 2. The rectangular interleaver may first perform a linear read-in row by row of the input bits. After performing linear read-in, the 2×3 rectangular interleaver may form a 2×3 matrix. Then the rectangular interleaver may perform a linear read-out column by column of the input bits. The first column of FIG. 17 shows indexes 0 and 3. The second column shows indexes 1 and 4. The third column shows indexes 2 and 5. Thus, the indexes of the interleaved bits B^{π} may be=0, 3, 1, 4, 2, 5. Linear read-out of the columns may output: subset A₁={0, 3}; subset A₂={1, 4}; and subset A₃={2, 5}.

Similarly, the method of transmitting information using polar codes of FIG. 6 may use a rectangular interleaver to perform step S602. A first data packet may comprise the information bits. Using rectangular interleaving, a transmitter may perform the interleaving operation which maps the first data packet based on a rectangular interleaving mapping algorithm.

FIG. 18 illustrates an example of subsets output by a triangular interleaver according to exemplary embodiments of the disclosure. FIG. 18 shows a triangular interleaver. FIG. 18 shows subsets A₁, A₂ and A₃ with equal size 2. The triangular interleaver may first perform a linear read-in row by row of the input bits. After performing linear read-in, the triangular interleaver may form a triangular matrix. Then the triangular interleaver may perform a linear read-out column by column of the input bits. The first column of FIG. 18 shows indexes 0, 1 and 3. The second column shows indexes 2 and 4. The third column shows index 5. Thus, the indexes of the interleaved bits B^{π} may be=0, 1, 3, 2, 4, 5. Linear read-out of the columns may output: subset A₁={0, 1}; subset A₂={3, 2}; and subset A₃={4, 5}.

Similarly, the method of transmitting information using polar codes of FIG. 6 may use a triangular interleaver to perform step S602. A first data packet may comprise the information bits. Using triangular interleaving, a transmitter may perform the interleaving operation which maps the first data packet based on a triangular interleaving mapping algorithm.

FIGS. 15, 16, 17 and 18 show a plurality of output subsets A₁, A₂ and A₃. As previously mentioned above, the subsets may correspond to sub-files in wireless caching. Each sub-file, if cached, may provide almost equal gain per cached bit. Thus, the subsets may provide improvement to the method of transmitting information using polar codes of FIG. 6. In step S603, instead of generating a second data packet, the transmitter may generate a plurality of subsets by partitioning the interleaved first data packet. A subset of the plurality of subsets may comprises a number of bits. In other words, the size of a subset is given by the number of bits in the subset. The plurality of subsets may comprise a first subset and a second subset, wherein the first subset and the second subset may have the same size. However, in another embodiment of the disclosure, the first subset and the second subset may have different sizes.

Additionally, in another embodiment of the disclosure, the method of transmitting information using polar codes of FIG. 6 may further comprise assigning reversed indexes of the unfrozen set to the information bits and generating the plurality of subsets. A first data packet may comprise the information bits. A transmitter may perform the method of FIG. 6, the method further comprising: selecting a frozen set of indexes from a polar sequence, the polar sequence comprising a plurality of indexes, wherein the indexes of the polar sequences are in increasing order of reliability, wherein the indexes of the frozen set have the lowest reliability; assigning the indexes of the frozen set to frozen bits of the polar code; selecting an unfrozen set of indexes from the polar sequence, wherein any index of the unfrozen set is not comprised in the frozen set, and any index of the frozen set is not comprised in the unfrozen set; reversing the order of the indexes of the unfrozen set; and assigning the reversed indexes of the unfrozen set to bits of the first packet data, wherein generating the second data packet comprising the interleaved first data packet comprises: generating a plurality of subsets by partitioning the interleaved first data packet, wherein reliability of the generated subsets is averaged.

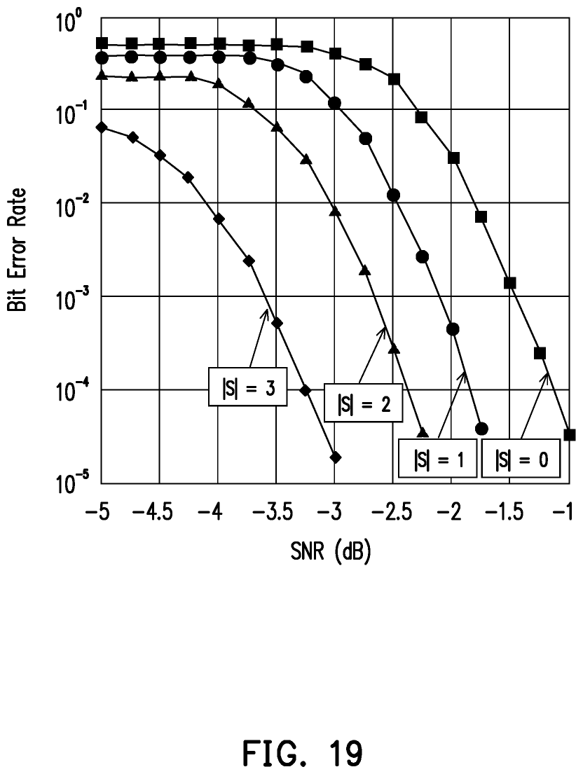

FIG. 19 illustrates Bit Error Rate (BER) performance of the polar code transmitter according to the exemplary embodiments of the disclosure. FIG. 19 shows BER performance for different S-interleavers. FIG. 19 shows that at low Signal-to-Noise Ratio (SNR), for example SNR=−5 dB, increasing |S| value provide a lower BER. Particularly, at SNR=−5 dB and |S|=3, BER<10⁻¹.

At BER=10⁻², increasing |S| from |S|=0 to |S|=1 provides a SNR gain of 0.7 dB. Further increasing |S| from |S|=1 to |S|=2 provides a SNR gain of 0.5 dB. Lastly, increasing |S| from |S|=2 to |S|=3 provides a SNR gain of 1 dB. At BER=10⁻³ and BER=10⁻⁴, similar SNR gains are provided. Thus, increasing |S| from |S|=0 to |S|=3 provides a SNR gain of 2.2 dB.

In view of the aforementioned descriptions, the disclosure is suitable for being used in a wireless communication system with polar codes. Polar codes are adopted in 5G communication systems to attain reliable transmission of data. Before data transmission, off-peak periods of low data transmission may be used to transmit partial information. Thus, the receiver may have partial prior information before decoding. Prior information may include information exchanged between users, infrequently updated data, etc.

The method and devices of the disclosure perform interleaving to average the reliability of the prior information of the information blocks or subsets. Since the receiver may already have partial prior information before decoding, error correction capability is improved and gain provided by the information subsets is equally distributed.

No element, act, or instruction used in the detailed description of disclosed embodiments of the present application should be construed as absolutely critical or essential to the present disclosure unless explicitly described as such. Also, as used herein, each of the indefinite articles “a” and “an” could include more than one item. If only one item is intended, the terms “a single” or similar languages would be used. Furthermore, the terms “any of” followed by a listing of a plurality of items and/or a plurality of categories of items, as used herein, are intended to include “any of”, “any combination of”, “any multiple of”, and/or “any combination of multiples of the items and/or the categories of items, individually or in conjunction with other items and/or other categories of items. Further, as used herein, the term “set” is intended to include any number of items, including zero. Further, as used herein, the term “number” is intended to include any number, including zero.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A method of transmitting information using polar code, the method comprising:
generating a first data packet with a predetermined size and comprising data of multiple applications or multiple users;
performing an interleaving operation which maps the first data packet based on a mapping algorithm to average the reliability of the data of multiple applications or multiple users; and
generating a second data packet comprising interleaved first data packet.

2. The method of claim 1, wherein the method further comprises:
selecting a frozen set of indexes from a polar sequence, the polar sequence comprising a plurality of indexes;
assigning the indexes of the frozen set to frozen bits of the polar code;
selecting an unfrozen set of indexes from the polar sequence; and
assigning the indexes of the unfrozen set to the first data packet.

3. The method of claim 2, wherein assigning the indexes of the unfrozen set to the first data packet comprises:
reversing the order of the indexes of the unfrozen set; and
assigning the reversed indexes of the unfrozen set to bits of the first packet data.

4. The method of claim 1, wherein performing the interleaving operation which maps the first data packet is based on a S-interleaving mapping algorithm.

5. The method of claim 1, wherein performing the interleaving operation which maps the first data packet is based on a rectangular interleaving mapping algorithm.

6. The method of claim 1, wherein performing the interleaving operation which maps the first data packet is based on a triangular interleaving mapping algorithm.

7. The method of claim 1, wherein generating the second data packet comprising the interleaved first data packet comprises:
generating a plurality of subsets by partitioning the interleaved first data packet.

8. A base station comprising:
a transmitter;
a receiver; and
a processor coupled to the transmitter and the receiver and configured to:
generate a first data packet with a predetermined size and comprising data of multiple applications or multiple users;
perform an interleaving operation which maps the first data packet based on a mapping algorithm to average the reliability of the data of multiple applications or multiple users; and
generate a second data packet comprising interleaved first data packet.

9. The base station of claim 8, where the processor is further configured to:
select a frozen set of indexes from a polar sequence, the polar sequence comprising a plurality of indexes;
assign the indexes of the frozen set to frozen bits of the polar code;
select an unfrozen set of indexes from the polar sequence; and
assign the indexes of the unfrozen set to the first data packet.

10. The base station of claim 9, wherein the processor is configured to assign the indexes of the unfrozen set to the first data packet comprising:
reverse the order of the indexes of the unfrozen set; and
assign the reversed indexes of the unfrozen set to bits of the first packet data.

11. The base station of claim 8, where the processor is configured to perform the interleaving operation which maps the first data packet based on a S-interleaving mapping algorithm.

12. The base station of claim 8, where the processor is configured to perform the interleaving operation which maps the first data packet based on a rectangular interleaving mapping algorithm.

13. The base station of claim 8, where the processor is configured to perform the interleaving operation which maps the first data packet based on a triangular interleaving mapping algorithm.

14. The base station of claim 8, where the processor is configured to generate the second data packet comprising interleaved first data packet by being configured to:
generate a plurality of subsets by partitioning the interleaved first data packet.

15. A user equipment (UE) comprising:
a transmitter;
a receiver; and
a processor coupled to the transmitter and the receiver and configured to:
generate a first data packet with a predetermined size and comprising data of multiple applications;
perform an interleaving operation which maps the first data packet based on a mapping algorithm to average the reliability of the data of multiple applications or multiple users; and
generate a second data packet comprising interleaved first data packet.

16. The UE of claim 15, where the processor is further configured to:
select a frozen set of indexes from a polar sequence, the polar sequence comprising a plurality of indexes;
assign the indexes of the frozen set to frozen bits of the polar code;
select an unfrozen set of indexes from the polar sequence; and
assign the indexes of the unfrozen set to the first data packet.

17. The UE of claim 16, wherein the processor is configured to assign the indexes of the unfrozen set to the first data packet comprising:
reverse the order of the indexes of the unfrozen set; and
assign the reversed indexes of the unfrozen set to bits of the first packet data.

18. The UE of claim 15, where the processor is configured to perform the interleaving operation which maps the first data packet based on a S-interleaving mapping algorithm.

19. The UE of claim 15, where the processor is configured to perform the interleaving operation which maps the first data packet based on a rectangular interleaving mapping algorithm.

20. The UE of claim 15, where the processor is configured to perform the interleaving operation which maps the first data packet based on a triangular interleaving mapping algorithm.
